(19) United States
(12) Patent Application Publication
(10) Pub. No.: US 2024/0053676 A1
(43) Pub. Date: Feb. 15, 2024

(54) INSPECTION METHOD FOR PELLICLE MEMBRANE OF LITHOGRAPHY SYSTEM

(71) Applicant: TAIWAN SEMICONDUCTOR MANUFACTURING COMPANY, LTD., Hsinchu (TW)

(72) Inventors: Chia Hao CHANG, Hsinchu City (TW); Pei-Cheng HSU, Taipei City (TW); Chih-Cheng CHEN, Hsinchu City (TW); Huan-Ling LEE, Hsinchu County (TW); Ting-Hao HSU, Hsinchu City (TW); Hsin-Chang LEE, Hsinchu County (TW)

(73) Assignee: TAIWAN SEMICONDUCTOR MANUFACTURING COMPANY, LTD., Hsinchu (TW)

(21) Appl. No.: 17/886,053

(22) Filed: Aug. 11, 2022

(51) Int. Cl. G03F 1/62

(52) U.S. Cl. CPC G03F 1/62

(57) ABSTRACT

A method includes performing a lithography process using a mask and a pellicle membrane; detaching the pellicle membrane from the mask after the lithography process is completed; performing an inspection process to the pellicle membrane, the inspection process including generating a laser beam toward the pellicle membrane from a laser source, such that the laser beam passes through the pellicle membrane; and generating an image by receiving the laser beam passing through the pellicle membrane using an image sensor; and determining whether a particle is present on the pellicle membrane or a pin hole is present in the pellicle membrane based on the image.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing. For these advances to be realized, similar developments in IC processing and manufacturing are needed. For example, the need to perform higher resolution lithography processes grows. One lithography technique is extreme ultraviolet lithography (EUVL).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system according to some embodiments of the present disclosure.

FIG. 2 is a schematic view of an EUV radiation source according to some embodiments of the present disclosure.

FIGS. 3A and 3B are schematic views of a mask and a pellicle structure according to some embodiments of the present disclosure.

FIG. 4A illustrates a schematic view of an inspection tool according to some embodiments of the present disclosure.

FIG. 4B illustrates a cross-sectional view of an inspection tool according to some embodiments of the present disclosure.

FIGS. 5A and 5B are schematic views of performing an inspection process to a pellicle membrane according to some embodiments of the present disclosure.

FIG. 5C is an explanatory result of an inspection process according to some embodiments of the present disclosure.

FIG. 6A is a schematic view of performing an inspection process to a pellicle membrane according to some embodiments of the present disclosure.

FIG. 6B is an explanatory result of an inspection process according to some embodiments of the present disclosure.

FIG. 7 illustrates a schematic view of an inspection tool according to some embodiments of the present disclosure.

FIGS. 8A and 8B are schematic views of performing an inspection process to a pellicle membrane according to some embodiments of the present disclosure.

FIG. 8C is an explanatory result of an inspection process according to some embodiments of the present disclosure.

FIG. 9A is a schematic view of performing an inspection process to a pellicle membrane according to some embodiments of the present disclosure.

FIG. 9B is an explanatory result of an inspection process according to some embodiments of the present disclosure.

FIG. 10 illustrates a method of an inspection process according to some embodiments of the present disclosure.

FIGS. 11A to 11F illustrate cross-sectional views of a pellicle membrane according to some embodiments of the present disclosure.

FIGS. 12A to 12F illustrate cross-sectional views of a pellicle membrane according to some embodiments of the present disclosure.

FIGS. 13A to 13F illustrate cross-sectional views of a pellicle membrane according to some embodiments of the present disclosure.

FIGS. 14A to 14F illustrate cross-sectional views of a pellicle membrane according to some embodiments of the present disclosure.

FIGS. 15A to 15F illustrate cross-sectional views of a pellicle membrane according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

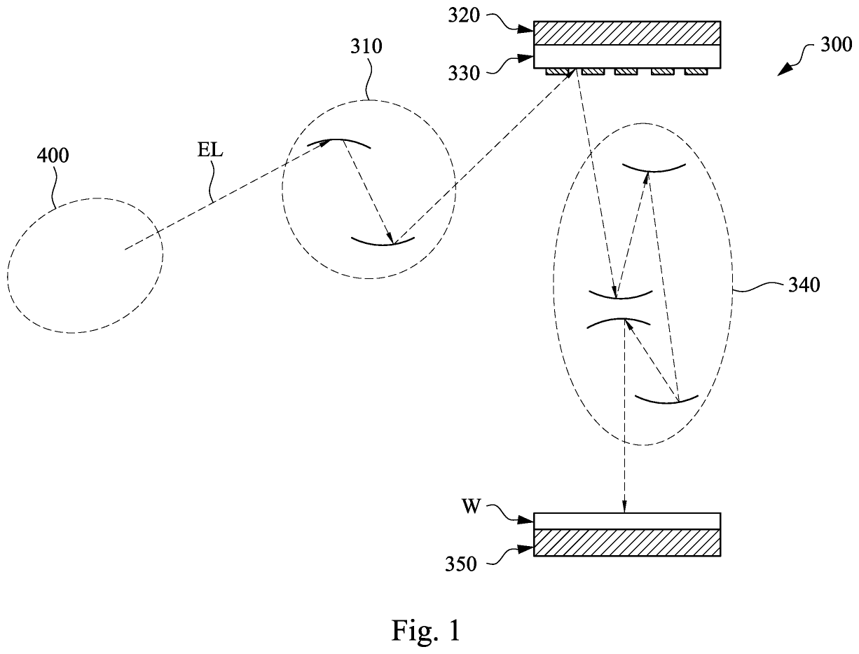

FIG. 1 is a schematic view of a lithography system according to some embodiments of the present disclosure. Shown there is a lithography system 300. In some embodiments, the lithography system 300 is an EUV lithography system. The EUV lithography system 300 is designed to expose a resist layer using EUV light (or EUV radiation). The resist layer is a material sensitive to the EUV light. The EUV lithography system 300 employs a radiation source 400 to generate EUV light EL, such as EUV light having a wavelength ranging between about 1 nm and about 100 nm. In some embodiments, the EUV light EL has a wavelength range centered at about 13.5 nm. Accordingly, the radiation source 400 is also referred to as an EUV radiation source 400. The EUV radiation source 400 may utilize a mechanism of laser-produced plasma (LPP) to generate the EUV radiation, which will be further described later.

The EUV lithography system 300 also employs an illuminator 310. In some embodiments, the illuminator 310 includes various reflective optics (e.g., a single mirror or a mirror system having multiple mirrors) for directing the light EL from the radiation source 400 onto a mask 330 secured on a mask stage 320. In some embodiments, the mask stage 320 includes an electrostatic chuck (e-chuck) used to secure the mask 330. In this context, the terms mask, photomask, and reticle are used interchangeably. In some embodiments, the mask 330 is a reflective mask.

The EUV lithography system 300 also includes a projection optics module (or projection optics box (POB)) 340 for imaging the pattern of the mask 330 onto a semiconductor substrate W (e.g., wafer) secured on a substrate stage (e.g., wafer stage) 350 of the EUV lithography system 300. The POB 340 includes reflective optics in the present embodiment. The EUV light EL that is directed from the mask 330 and carries the image of the pattern defined on the mask 330 is collected by the POB 340. The illuminator 310 and the POB 340 may be collectively referred to as an optical module of the EUV lithography system 300. In the present embodiment, the semiconductor substrate W is a semiconductor wafer, such as a silicon wafer or other type of wafer to be patterned. The semiconductor substrate W is coated with a resist layer sensitive to the EUV light EL in the present embodiment. Various components including those described above are integrated together and are operable to perform EUV lithography exposing processes.

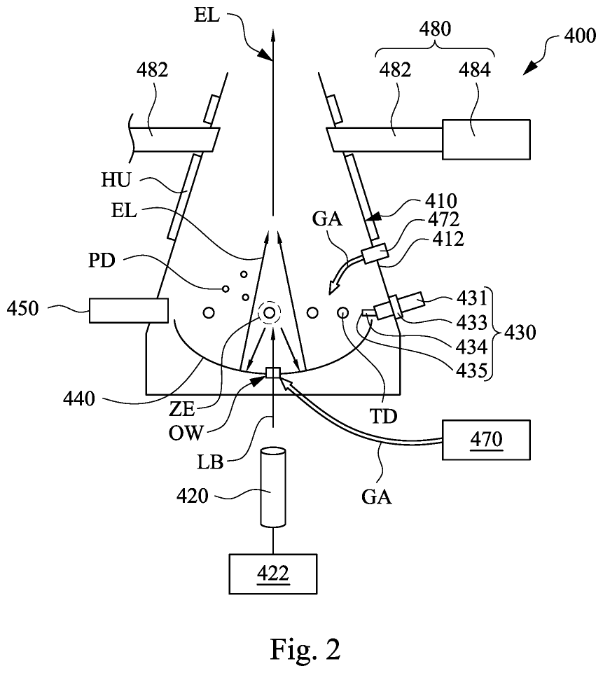

FIG. 2 is a schematic view of an EUV radiation source 400 according to some embodiments of the present disclosure. The radiation source 400 employs a laser produced plasma (LPP) mechanism to generate plasma and further generate EUV light from the plasma. The radiation source 400 includes a vessel 410, a laser source 420, a target droplet generator 430, a collector 440, and a droplet catcher 450.

In some embodiments, the target droplets TD are metal droplets, such as droplets of tin (Sn), lithium (Li), or an alloy of Sn and Li. In some embodiments, the target droplets TD each have a diameter in a range from about 10 microns (μm) to about 100 μm. For example, in an embodiment, the target droplets TD are tin droplets, having a diameter of about 10 μm to about 100 μm. In other embodiments, the target droplets TD are tin droplets having a diameter of about 25 μm to about 50 μm. In some embodiments, the target droplets TD are supplied through a nozzle 435 of the droplet generator 430 at a rate in a range from about 50 droplets per second (i.e., an ejection-frequency of about 50 Hz) to about 50,000 droplets per second (i.e., an ejection-frequency of about 50 kHz). In some embodiments, the target droplets TD are supplied at an ejection-frequency of about 100 Hz to about 25 kHz. In other embodiments, the target droplets TD are supplied at an ejection frequency of about 500 Hz to about 10 kHz. The target droplets TD are ejected through the nozzle 435 and into a zone of excitation ZE at a speed in a range of about 10 meters per second (m/s) to about 100 m/s in some embodiments. In some embodiments, the target droplets TD have a speed of about 10 m/s to about 75 m/s. In other embodiments, the target droplets TD have a speed of about 25 m/s to about 50 m/s.

In some embodiments, an excitation laser LB generated by the excitation laser source 420 is a pulse laser. The excitation laser LB is generated by the excitation laser source 420. In some embodiments, the laser source 420 includes a carbon dioxide (CO₂) or a neodymium-doped yttrium aluminum garnet (Nd:YAG) laser source with a wavelength in the infrared region of the electromagnetic spectrum. For example, the laser source 420 has a wavelength of 9.4 μm or 10.6 μm, in an embodiment.

In some embodiments, the excitation laser LB includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In some embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In some embodiments, the pre-heat laser and the main laser have an average power in the range from about 1 kilowatt (kW) to about 50 kW. The pulse-frequency of the excitation laser LB is matched with the ejection-frequency of the target droplets TD in some embodiments.

The excitation laser LB is directed through a window OW in the collector 440 into the zone of excitation ZE. The window OW is made of a suitable material substantially transparent to the excitation laser LB. The generation of the pulse lasers is synchronized with the ejection of the target droplets TD through the nozzle 435. As the target droplets TD move through the excitation zone ZE, the pre-pulses heat the target droplets TD and transform them into low-density target plumes. A delay between the pre-pulse and the main pulse is controlled to allow the target plume to form and to expand to an optimal size and geometry. In some embodiments, the pre-pulse and the main pulse have the same pulse-duration and peak power. When the main pulse heats the target plume, a high-temperature plasma is generated. The plasma emits EUV radiation EL, which is collected by the collector 440. The collector 440 further reflects and focuses the EUV radiation EL toward the illuminator 310 (as shown in FIG. 1) for the lithography exposing processes. The droplet catcher 450 is used for catching excessive target droplets. For example, some target droplets may be purposely missed by the laser pulses.

In some embodiments, the collector 440 is designed with a proper coating material and shape to function as a mirror for EUV collection, reflection, and focusing. In some embodiments, the collector 440 is designed to have an ellipsoidal geometry. In some embodiments, the coating material of the collector 440 is similar to the reflective multilayer of the EUV mask 330 (as shown in FIG. 1). In some embodiments, the coating material of the collector 440 includes a ML (such as one or more Mo/Si film pairs) and may further include a capping layer (such as Ru) coated on the ML to substantially reflect the EUV light EL. In some embodiments, the collector 440 may further include a grating structure designed to effectively scatter the laser beam directed onto the collector 440. For example, a silicon nitride layer is coated on the collector 440 and is patterned to have a grating pattern.

In some embodiments, the high-temperature plasma may cool down and become vapors or small particles (collectively, debris) PD. The debris PD may deposit onto the surface of the collector 440, thereby causing contamination thereon. Over time, the reflectivity of the collector 440 degrades due to debris accumulation and other factors such as ion damages, oxidation, and blistering. Once the reflectivity is degraded to a certain degree, the collector 440 reaches the end of its usable lifetime and may need to be swapped out (i.e., replaced with a new collector).

The vessel 410 has a cover 412 for ventilation and for collecting debris PD. In some embodiments, the cover 412 is made of a suitable solid material, such as stainless steel. The cover 412 is designed and disposed around the collector 440. The cover 412 may include a plurality of vanes, which are evenly spaced around the cone-shaped cover 412. In some embodiments, the radiation source 400 further includes a heating unit HU disposed around part of the cover 412. The heating unit HU functions to maintain the temperature inside the cover 412 above a melting point of the debris PD so that the debris PD does not solidify on the inner surface of the cover 412. When the debris PD vapor comes in contact with the vanes, it may condense into a liquid form and flow into a lower section of the cover 412. The lower section of the cover 412 may provide holes (not shown) for draining the debris liquid out of the cover 412.

In some embodiments, a buffer gas GA is supplied from a first buffer gas supply 470 through the aperture in collector 440 by which the pulse laser is delivered to the tin droplets. In some embodiments, the buffer gas is H2, He, Ar, N2 or another inert gas. In certain embodiments, H radicals generated by ionization of the H2 buffer gas is used for cleaning purposes. The buffer gas GA can also be provided through one or more second buffer gas supplies 272 toward the collector 440 and/or around the edges of the collector 440. Further, the vessel 410 further includes an exhaust system 280 so that the buffer gas is exhausted outside the vessel 410.

Hydrogen gas has low absorption to the EUV radiation. Hydrogen gas reaching the coating surface of the collector 440 reacts chemically with a metal of the droplet forming a hydride, e.g., metal hydride. When tin (Sn) is used as the droplet TD, stannane (SnH₄), which is a gaseous byproduct of the EUV generation process, is formed. The gaseous SnH₄ is then pumped out through the exhaust system 480.

The buffer gas GA is provided for various protection functions, which include effectively protecting the collector 440 from the contaminations by tin particles. Other suitable gas may be alternatively or additionally used. The gas GA may be introduced into the collector 440 through openings (or gaps) near the output window OW through one or more gas pipelines. The exhaust system 480 includes one or more exhaust lines 482 and one or more pumps 484. The exhaust line 482 is connected to the wall of the vessel 410 for receiving the exhaust. In some embodiments, the cover 412 is designed to have a cone shape with its wide base integrated with the collector 440 and its narrow top section facing the illuminator 310 (FIG. 1). To further these embodiments, the exhaust line 482 is connected to the cover 412 at its top section. Installing the exhaust line 482 at the top section of the cover 412 helps exhaust the debris PD out of the space defined by the collector 440 and the cover 412. The space in the vessel 410 is maintained in a vacuum environment since the air absorbs the EUV radiation.

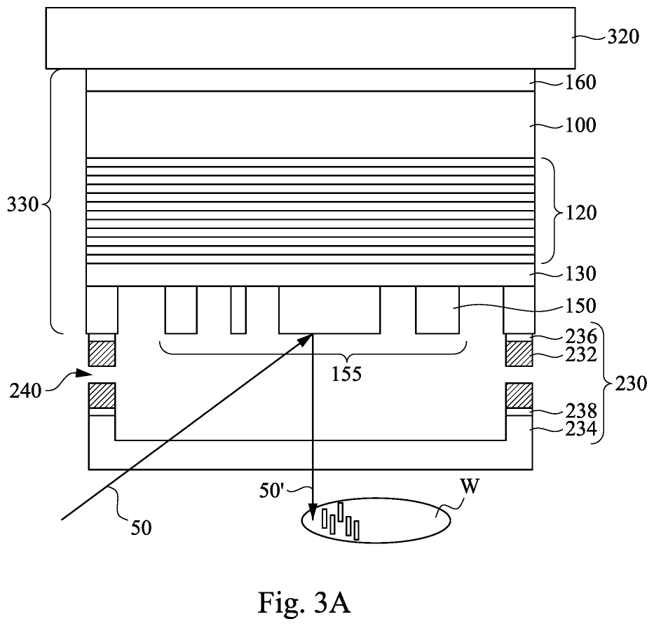

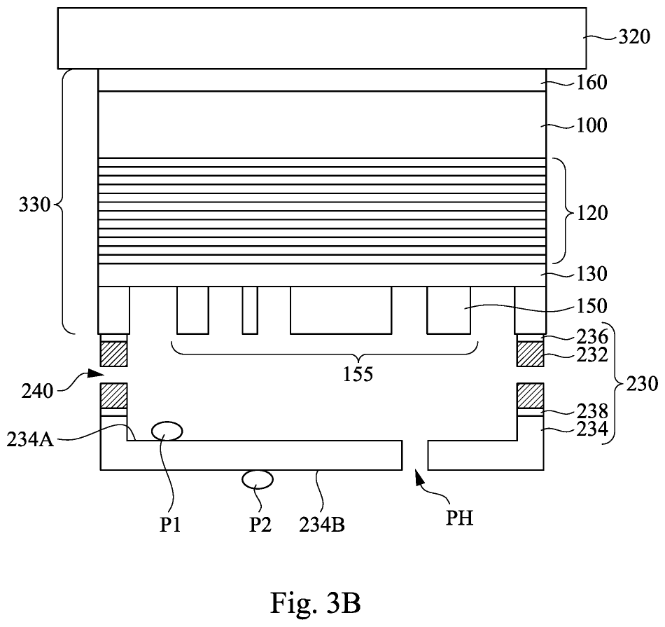

FIGS. 3A and 3B are schematic views of a mask and a pellicle structure according to some embodiments of the present disclosure. Some elements of FIGS. 3A and 3B are similar to those described in FIGS. 1 and 2, such elements are labeled the same, and relevant details will not be repeated for brevity.

Reference is made to FIG. 3A. Shown there is a mask 330 secured on a mask stage 320. The mask 330 may be an EUV mask. In some embodiments, the EUV mask 330 includes a substrate 100, reflective multilayer (ML) 120 disposed on the substrate 100, a capping layer 130 disposed on the reflective ML 120, and an absorption layer 150 disposed on the capping layer 130. Moreover, a conductive backside coating 160 is disposed on a backside of the substrate 100.

In some embodiments, the substrate 100 may be made of low thermal expansion material (LTEM). In some embodiments, the LTEM material may include quartz, silicon, silicon carbide, and silicon oxide-titanium oxide compound. Alternatively, the LTEM material may include TiO₂ doped SiO₂, and/or other low thermal expansion materials known in the art. During operation, the LTEM substrate 100 serves to reduce image distortion due to mask heating. In some embodiments, the LTEM substrate 100 includes materials with a low defect level and a smooth surface.

The reflective ML 120 is formed over the substrate 100. According to Fresnel equations, light reflection occurs when light propagates across the interface between two materials of different refractive indices. Light reflection is larger when the difference of refractive indices is larger. To increase light reflection, one may also increase the number of interfaces by forming a multilayer of alternating materials and let light to be reflected from different interfaces interfere constructively by choosing appropriate thickness for each layer inside the multilayer. However, the absorption of the employed materials for the multilayer limits the highest reflectivity that can be achieved. The reflective ML 120 includes a plurality of film pairs, such as molybdenum-silicon (Mo/Si) film pairs (e.g., a layer of molybdenum above or below a layer of silicon in each film pair). Alternatively, the reflective ML 120 may include molybdenum-beryllium (Mo/Be) film pairs, or any two materials or material combinations with large difference in refractive indices and small extinction coefficients. The thickness of each layer of the reflective ML 120 depends on the wavelength of the incident light and the angle of incidence on the mask. For a specified angle of incidence, the thickness of the reflective ML 120 is adjusted to achieve maximal constructive interference for lights reflected at different interfaces of the ML 120.

The capping layer 130 includes a material that protects the reflective ML 120 during processing of the mask (for example, during etching of an absorption layer of the mask). In the depicted embodiments, the capping layer 130 includes a ruthenium-containing material, such as Ru, RuNb, RuZr, RuMo, RuY, RuB, RuTi, RuLa, other ruthenium-containing material, or combinations thereof. Alternatively, the capping layer 130 includes a chromium-containing material, such as Cr, CrN, CrO, CrC, CrON, CrCN, CrOC, CrOCN, other chromium-containing material, or combinations thereof. In yet another alternative, the capping layer 130 includes materials other than ruthenium-containing materials and chromium-containing materials. The capping layer 130 may include a combination of ruthenium-containing material, chromium-containing material, and other material, for example, where the capping layer 130 includes multiple layers. In an example, the capping layer 130 has a thickness of about 2 nm to about 5 nm. includes a material that protects the reflective ML 120 during processing of the mask (for example, during etching of an absorption layer of the mask). In some embodiments, the capping layer 130 may be formed by suitable deposition process, such as a physical vapor deposition (PVD) process, a chemical vapor deposition (CVD) process, or the like.

The absorption layer 150 includes one or more layers designed to absorb radiation in the radiation type/wavelength range projected onto the mask. In the depicted embodiments, the one or more layers of the absorption layer 150 are designed to absorb EUV radiation. The one or more layers include various materials, such as tantalum-containing materials (for example, Ta, TaN, TaNH, TaHF, TaHfN, TaBSi, TaB-SiN, TaB, TaBN, TaSi, TaSiN, TaGe, TaGeN, TaZr, TaZrN, other tantalum-containing materials, or combinations thereof), chromium-containing materials (for example, Cr, CrN, CrO, CrC, CrON, CrCN, CrOC, CrOCN, other chromium-containing material, or combinations thereof), titanium-containing materials (for example, Ti, TiN, other titanium-containing material, or combinations thereof), other suitable materials, or combinations thereof. A configuration of the one or more layers (such as material composition of the one or more layers) is selected to provide process flexibility during fabrication of the mask 330. For example, etching characteristics of the one or more layers of the absorption layer 150 provide process flexibility, which can reduce manufacturing time and costs. In some embodiments, the absorption layer 150 is patterned with pattern features 155 to define a layout pattern for layer of an integrated circuit (IC).

In some embodiments, the backside coating 160 may include chromium nitride (CrN) or Tantalum boride (TaB) and has a thickness of 20 nm to 100 nm. In some embodiments, the mask 330 can be secured to the mask stage 320 through the backside coating 160 via electromagnetic force.

During performing a lithography process, a pellicle structure 230 is attached to the mask 330. In some embodiments, the pellicle structure 230 may include a pellicle frame 232 and a pellicle membrane 234. The pellicle frame 232 is attached to the front side of the mask 330 by a frame adhesive 236. The pellicle membrane 234 extends over the pattern features 155 of the absorption layer 150 and has a periphery region attached the pellicle frame 232 by a membrane adhesive 238.

The pellicle frame 232 is configured to properly secure the pellicle membrane 234 to the mask 330. The pellicle frame 232 has a round-shape top view, a rectangular-shape top view, or any other suitable shape, and is mounted onto a border region of the mask 330. In some embodiments, the pellicle frame 232 is attached to the border region of the absorption layer 150. Here, the “border region” of the absorption layer 150 can be referred to as the region of the absorption layer 150 other than the pattern features 155. In some embodiments, the border region of the absorption layer 150 may surround the pattern features 155 of the absorption layer 150.

The pellicle frame 232 includes a rigid material. In some embodiments, the pellicle frame 232 includes Al, Al-alloy, titanium (Ti), nickel (Ni), gold (Au), silver (Ag), copper (Cu), Mo, platinum (Pt), Cr, manganese (Mn), iron (Fe), Co, palladium (Fd), Ta, W, silicon, polymer, other suitable materials, and/or combinations thereof. In some embodiments, the pellicle frame 232 has a coefficient of thermal expansion (CTE) similar to that of the mask 330 in order to reduce stress exerted on the mask 330 resulting from changes in temperature.

The pellicle frame 232 is attached to the front side of the mask 330 by frame adhesive 236. In some embodiments, the frame adhesive 236 includes a pressure sensitive adhesive. In some embodiments, the frame adhesive 236 includes a thermosetting adhesive material, e.g., epoxy resin, benzocyclobutene (BCB), methylsilsesqulxane (MSQ), polyimide, other thermosetting materials, and/or combinations thereof. In some embodiments, the frame adhesive 236 includes a glue or another material configured to secure the pellicle frame 232 to the mask 330. In some embodiments, the pellicle frame 232 is secured to the mask 330 in a manner other than pellicle adhesive 236, such as at least one suction cup, a vacuum, or an electrostatic sticker. In such embodiments, the pellicle adhesive 236 is omitted.

In some embodiments, the pellicle frame 232 may include vent holes 240. The vent holes 240 may allow air traveling in and out of the space between the pellicle structure 230 and the mask 330. In some embodiments, the vent holes 240 may prevent rupture of the pellicle membrane 234 when the mask 330 undergoes a sudden pressure change.

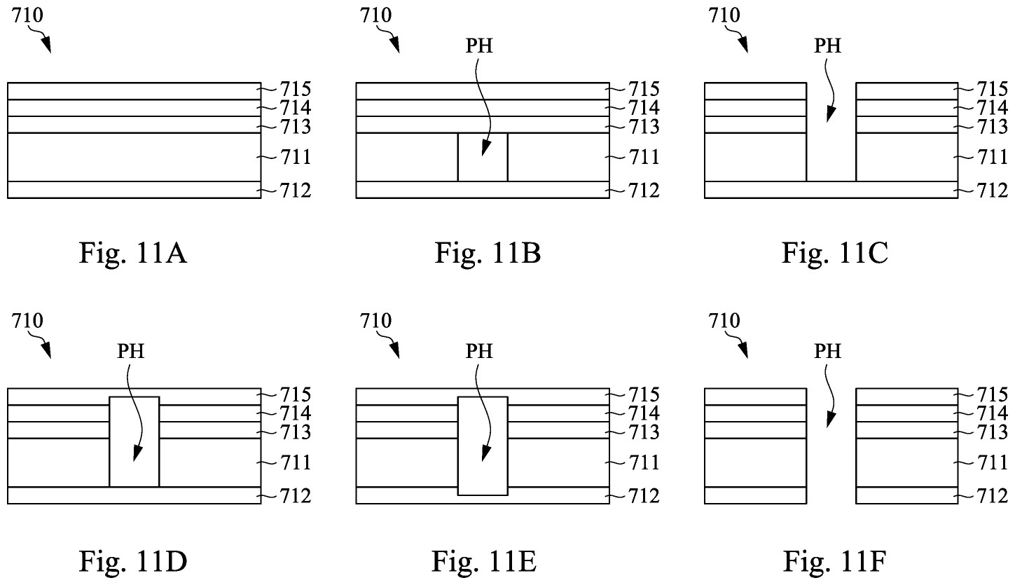

The pellicle membrane 234 is a film stretched over the pellicle frame 232. The pellicle membrane 234 includes a material having sufficient mechanical strength to avoid warping to an extent that would negatively impact a photolithography process when attached to pellicle frame 232. In some embodiments, the pellicle membrane 234 may include a material that is transparent to the UV radiation source, e.g., transparent to the DUV or EUV radiation source of the lithography process. Material of the pellicle membrane 234 will be described in FIGS. 11A to 15F.

The pellicle membrane 234 is attached to the pellicle frame 232 by membrane adhesive 238. In some embodiments, the membrane adhesive 238 includes a thermosetting adhesive material such as, for example, epoxy resin, acrylic resin, fluorine resin, BCB, MSQ, polyimide, other thermosetting materials, and/or combinations thereof. In some embodiments, the membrane adhesive 238 includes a glue or another material configured to secure the pellicle membrane 234 to the pellicle frame 232. In some embodiments, the membrane adhesive 238 has a same material as the frame adhesive 236. In some embodiments, the membrane adhesive 238 has a different material from the frame adhesive 236.

During a lithography process, a radiation beam 50 that is originated from an EUV light source, e.g., the radiation source 400 of FIG. 2. In some embodiments, the radiation beam 50 may be similar to the EUV light EL as described in FIGS. 1 and 2. The radiation beam 50 is directed to the mask 330 through the pellicle membrane 234 of the pellicle structure 230, and the radiation beam 50′ is reflected from the reflective mask 330 and is incident onto the wafer W. In some embodiments, the radiation beam 50′ may be incident onto the wafer W through the POB 340 as described in FIG. 1.

Reference is made to FIG. 3B. During the lithography process, the pellicle membrane 234 of the pellicle structure 230 may include a first side 234A facing the pattern features 155 of the absorption layer 150 of the mask 330, and may include a second side 234B distal to the mask 330. That is, the first side 234A of the pellicle membrane 234 is opposite to the second side 234B of the pellicle membrane 234.

During the lithography process, there are several factors that may affect the quality of the lithography process. In some embodiments, at least one particle P1 that fall on the first side 234A of the pellicle membrane 234 may affect the incident radiation beam (e.g., the radiation beam 50 of FIG. 3A), and the pattern of the particle P1 may also be printed on the wafer and may cause critical dimension (CD) error. Moreover, the particle P1 may also fall on the mask 330 and cause contamination to the mask 330. Similarly, at least one particle P2 that fall on the second side 234B of the pellicle membrane 234 may also affect the incident radiation beam (e.g., the radiation beam 50 of FIG. 3A), and the pattern of the particle P2 may be printed on the wafer and may cause critical dimension (CD) error as well. In some embodiments, multiple particles P1 may present on the first side 234A of the pellicle membrane 234, and multiple particles P2 may present on the second side 234B of the pellicle membrane 234.

The pellicle membrane 234 of the pellicle structure 230 may include at least one pin hole PH. The pin hole PH may be formed in the pellicle membrane 234 during fabrication of the pellicle membrane 234. As illustrated in FIG. 3B, the pin hole PH is illustrated penetrating through the pellicle membrane 234. However, in some other embodiments, the pin hole PH may not penetrate through the pellicle membrane 234. In some embodiments, the pellicle membrane 234 may be exposed to a hydrogen (H₂) environment during the lithography processes. The H₂ flow may cause erode the pellicle membrane 234, and thus the pin hole PH may be enlarged during several lithography processes. The enlarged pin hole PH will cause rupture to the pellicle membrane 234, and the debris of the pellicle membrane 234 may fall on the mask 330 and the chamber, and will cause mask contamination and chamber contamination, which will deteriorate the lithography quality. In some embodiments, multiple pin holes PH are present in the pellicle membrane 234.

The present disclosure provides a method for inspecting a pellicle membrane by determining whether particles are present on surfaces of the pellicle membrane and by determining whether the pellicle membrane has pin hole.

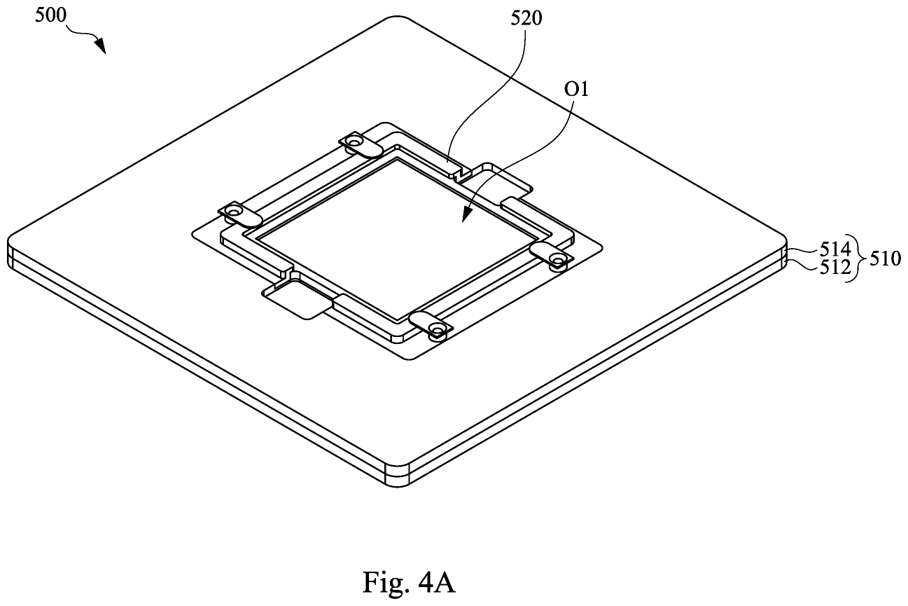

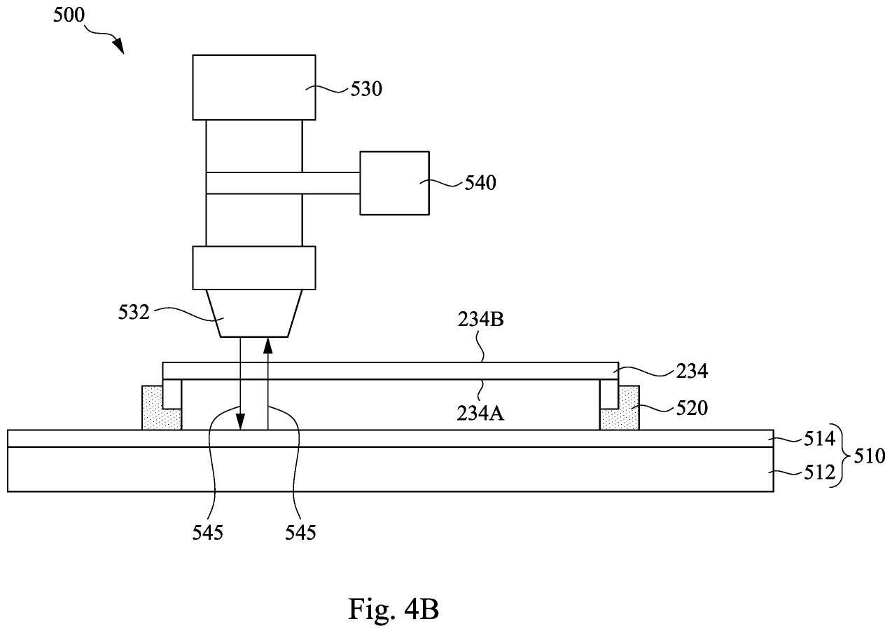

FIG. 4A illustrates a schematic view of an inspection tool according to some embodiments of the present disclosure. FIG. 4B illustrates a cross-sectional view of an inspection tool according to some embodiments of the present disclosure.

In FIGS. 4A and 4B, an inspection tool 500 is illustrated. The inspection tool 500 is used to determine whether particles are present on surfaces of the pellicle membrane or to determine whether the pellicle membrane has pin hole. The inspection tool 500 includes a reflector 510 having a plate 512 and a reflective film 514 disposed on the plate 512. In some embodiments, the plate 512 may be a quartz plate, or may be other suitable materials. In some embodiments, the reflective film 514 may include metal, such as Cr, Au, Ag, Ni, Co, Fe, or Pt, or combinations thereof. The reflective film 514 may also include oxide of Cr, Au, Ag, Ni, Co, Fe, or Pt. In some other embodiments, the reflective film 514 may include CrON, MoSi, SiON, SiN, or other suitable material. In some embodiments, the thickness of the reflective film 514 of the reflector 510 is in a range from about 5 nm to about 100 nm. In some embodiments, the surface roughness of the reflective film 514 is lower than about 0.5 nm.

A pellicle holder 520 is connected to the reflector 510. The pellicle holder 520 is configured to fix a pellicle membrane. For example, as shown in FIG. 4A, the pellicle holder 520 has a rectangular shape, and has an opening O1 that exposes the surface of the reflective film 514 of the reflector 510. As shown in FIG. 4B, the pellicle holder 520 has a slot that can accommodate the pellicle membrane 234. In greater details, the border of the pellicle membrane 234 can be placed in the slot of the pellicle holder 520. When the pellicle membrane 234 is placed on the pellicle holder 520, the first side 234A of the pellicle membrane 234 faces the reflective film 514 of the reflector 510, while the second side 234B of the pellicle membrane 234 faces away from the reflective film 514 of the reflector 510.

The inspection tool 500 further includes an image sensor 530 and an object lens 532. In some embodiments, the image sensor 530 may include charge coupled device (CCD), complementary metal oxide semiconductor sensor (CMOS sensor), or other suitable image sensor. A laser source 540 is coupled to the image sensor 530. In greater details, the laser source 540 is configured to generate a laser beam 545 toward the reflective film 514 of the reflector 510, and the reflective film 514 may reflect the laser beam 545. The reflected laser beam 545 passes through the object lens 532 and is received by the image sensor 530. Accordingly, the image sensor 530 can generate an image based on the reflected laser beam 545.

In some embodiments, the laser beam 545 can be continuous laser or pulse laser. In some embodiments, the wavelength of the laser beam 545 may be in a range from about 400 nm to about 600 nm. In some other embodiments, the wavelength of the laser beam 545 may be lower than 400 nm. In some embodiments, the numerical aperture (NA) of the object lens 532 is in a range from about 0.25 to about 0.5.

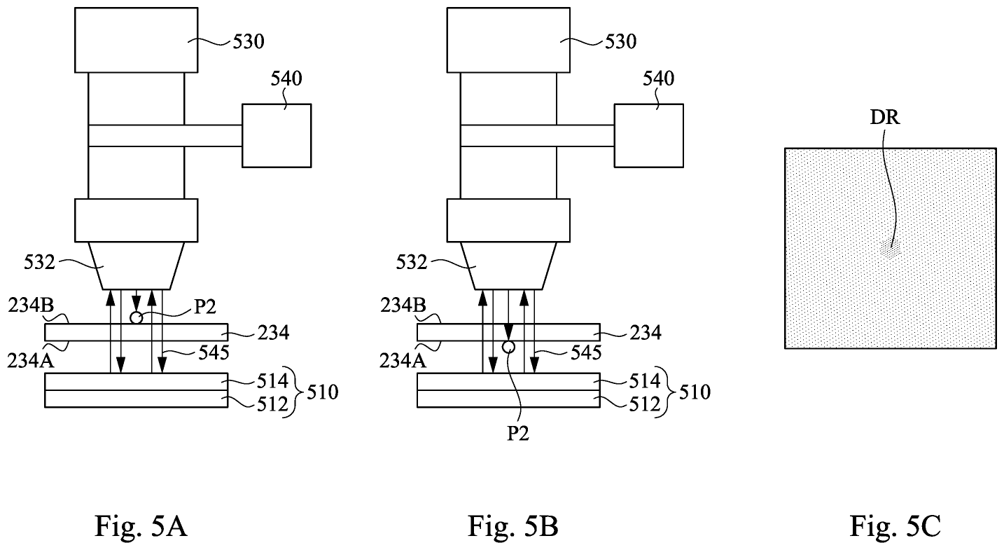

FIGS. 5A and 5B are schematic views of performing an inspection process to a pellicle membrane according to some embodiments of the present disclosure. FIG. 5C is an explanatory result of an inspection process according to some embodiments of the present disclosure.

When an inspection process is performed to the pellicle membrane 234, the pellicle membrane 234 is placed on the pellicle holder 520 (see FIGS. 4A and 4B), such that the pellicle membrane 234 is between the reflective film 514 of the reflector 510 and the image sensor 530 (and the laser source 540). The laser source 540 may generate the laser beam 545 toward the reflective film 514 of the reflector 510, in which the laser beam 545 may pass through the pellicle membrane 234 prior to reaching the reflective film 514. The reflective film 514 reflects the laser beam 545, the reflected laser beam 545 may pass through the pellicle membrane 234 again and will be received by the image sensor 530.

FIG. 5A shows a condition where a particle P2 is present on the second side 234B of the pellicle membrane 234. In such condition, the particle P2 may block a portion of the incident laser beam 545 generated by the laser source 540, such that the portion of the incident laser beam 545 may not reach the reflective film 514. On the other hand, other portions of the incident laser beam 545 that are not blocked by the particle P2 may pass through the pellicle membrane 234 to the reflective film 514, and will be reflected back to the image sensor 530 as described above.

FIG. 5B shows a condition where a particle P1 is present on the first side 234A of the pellicle membrane 234. In such condition, the particle P1 may block a portion of the incident laser beam 545 generated by the laser source 540, such that the portion of the incident laser beam 545 may not reach the reflective film 514. On the other hand, other portions of the incident laser beam 545 that are not blocked by the particle P1 may pass through the pellicle membrane 234 to the reflective film 514, and will be reflected back to the image sensor 530 as described above.

FIG. 5C is an explanatory result of the inspection process described in FIGS. 5A and 5B. In greater details, FIG. 5C is an image generated by the image sensor 530. In the embodiments where particle (e.g., particle P1 or P2) is present on the surface of the pellicle membrane 234, the particle may block the incident laser beam 545 generated by the laser source 540. Accordingly, the blocked laser beam 545 may not be reflected back to the image sensor 530. As a result, a dark region DR may be present in the generated image. Stated another way, if a dark region DR is present in the generated image, this may indicate that a particle is present on the surface of the pellicle membrane 234. In some embodiments, the “dark region” can be referred to as a region that is darker than the background of the generated image, in which the background can be referred to as the region with no particle or pin hole.

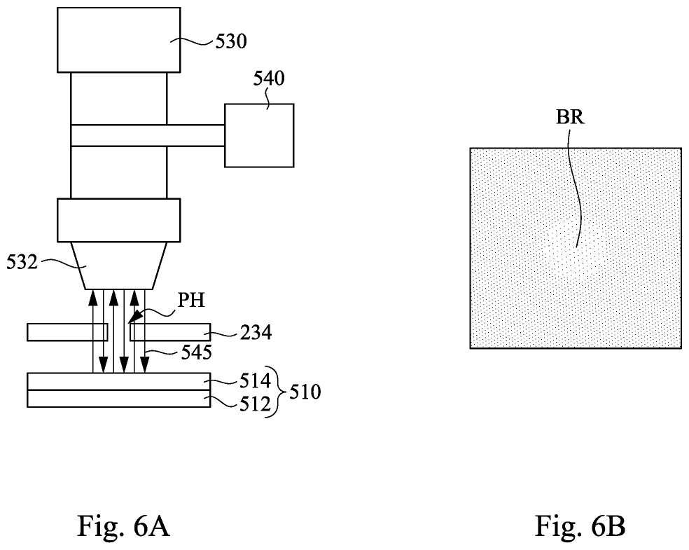

FIG. 6A is a schematic view of performing an inspection process to a pellicle membrane according to some embodiments of the present disclosure. FIG. 6B is an explanatory result of an inspection process according to some embodiments of the present disclosure. Some details of FIG. 6A may be similar to those described with respect to FIGS. 5A and 5B, and will not be repeated for brevity.

FIG. 6A shows a condition where a pin hole PH is present in the pellicle membrane 234. In such condition, a portion of the incident laser beam 545 may pass through the pine hole PH to the reflective film 514, and is reflected back to the image sensor 530. On the other hand, other portions of the incident laser beam 545 may pass through the pellicle membrane 234 to the reflective film 514, and will be reflected back to the image sensor 530.

FIG. 6B is an explanatory result of the inspection process described in FIG. 6A. In greater details, FIG. 6B is an image generated by the image sensor 530. In the embodiments where pin hole (e.g., the pin hole PH) is present in the pellicle membrane 234, the incident laser beam 545 may pass through both the pine hole PH and the pellicle membrane 234 to the reflective film 514, and will be reflected back to the image sensor 530. However, because the pellicle membrane 234 may scatter the incident laser beam 545, and will reduce the light intensity of the incident laser beam 545 and the reflected laser beam 545. In contrast, light intensity of the incident laser beam 545 and the reflected laser beam 545 that passes through the pine hole PH may not be reduced (or less reduced than the portion of the laser beam 545 passing through the pellicle membrane 234). As a result, a bright region BR may be present in the generated image. Stated another way, if a bright region BR is present in the generated image, this may indicate that a pin hole is present in the pellicle membrane 234. In some embodiments, the “bright region” can be referred to as a region that is brighter than the background of the generated image, in which the background can be referred to as the region with no particle or pin hole.

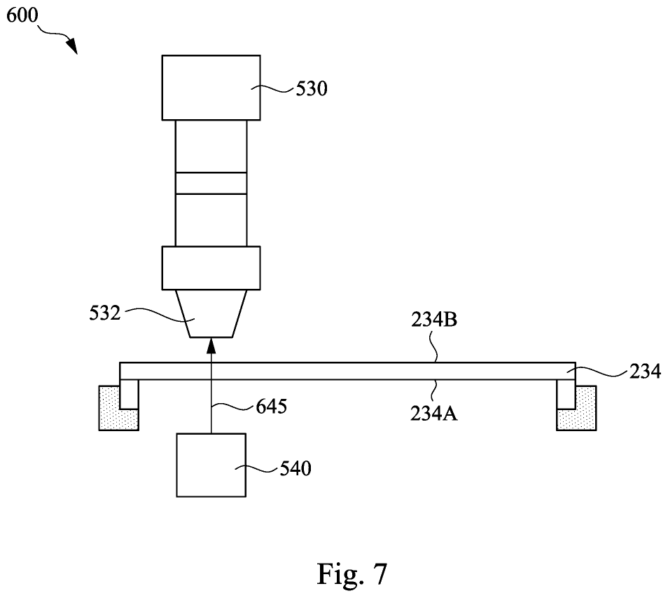

FIG. 7 illustrates a schematic view of an inspection tool according to some embodiments of the present disclosure. Some elements of FIG. 7 is similar to those described in FIGS. 4A and 4B, such elements are labeled the same and relevant details will not be repeated for brevity.

In FIG. 7, an inspection tool 600 is illustrated. The inspection tool 600 is different from the inspection tool 500 described in FIGS. 4A and 4B, in that the reflector 510 of FIGS. 4A and 4B is omitted in the embodiments of FIG. 7. In the embodiments of FIG. 7, the image sensor 530 and the laser source 540 are disposed on opposite sides of the pellicle membrane 234 during the inspection process. The pellicle membrane 234 is placed on the pellicle holder 520 during the inspection process, and the pellicle membrane 234 is between the image sensor 530 and the laser source 540. The laser source 540 is optically coupled to the image sensor 530, in which the laser source 540 is aimed at the image sensor 530, so as to generate a laser beam 645 toward the image sensor 530. The laser beam 645 passes through the object lens 532 and is received by the image sensor 530. Accordingly, the image sensor 530 can generate an image based on the laser beam 545.

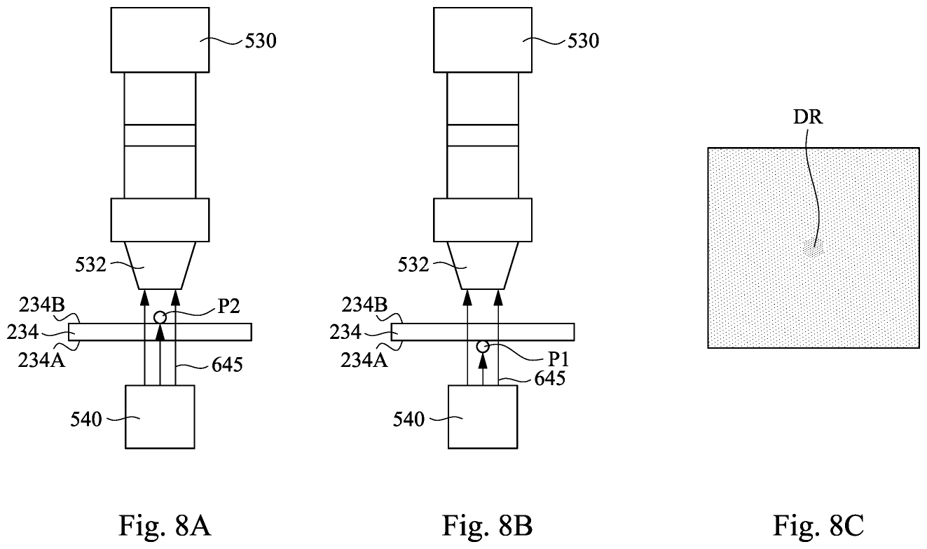

FIGS. 8A and 8B are schematic views of performing an inspection process to a pellicle membrane according to some embodiments of the present disclosure. FIG. 8C is an explanatory result of an inspection process according to some embodiments of the present disclosure.

When an inspection process is performed to the pellicle membrane 234, the pellicle membrane 234 is placed on the pellicle holder 520, such that the pellicle membrane 234 is between the image sensor 530 and the laser source 540. The laser source 540 may generate the laser beam 645 toward the image sensor 530 that is on the opposite side of the pellicle membrane 234. The laser beam 645 may pass through the pellicle membrane 234 and is received by the image sensor 530.

FIG. 8A shows a condition where a particle P2 is present on the second side 234B of the pellicle membrane 234. In such condition, the particle P2 may block a portion of the incident laser beam 645 generated by the laser source 540, such that the portion of the incident laser beam 645 may not reach the image sensor 530. On the other hand, other portions of the incident laser beam 645 that are not blocked by the particle P2 may pass through the pellicle membrane 234 to the image sensor 530.

FIG. 8B shows a condition where a particle P1 is present on the first side 234A of the pellicle membrane 234. In such condition, the particle P1 may block a portion of the incident laser beam 645 generated by the laser source 540, such that the portion of the incident laser beam 545 may not reach the image sensor 530. On the other hand, other portions of the incident laser beam 645 that are not blocked by the particle P1 may pass through the pellicle membrane 234 to the image sensor 530.

FIG. 8C is an explanatory result of the inspection process described in FIGS. 8A and 8B. In greater details, FIG. 8C is an image generated by the image sensor 530. In the embodiments where particle (e.g., particle P1 or P2) is present on the surface of the pellicle membrane 234, the particle may block the incident laser beam 645 generated by the laser source 540. Accordingly, the blocked laser beam 645 may not reach the image sensor 530. As a result, a dark region DR may be present in the generated image. Stated another way, if a dark region DR is present in the generated image, this may indicate that a particle is present on the surface of the pellicle membrane 234.

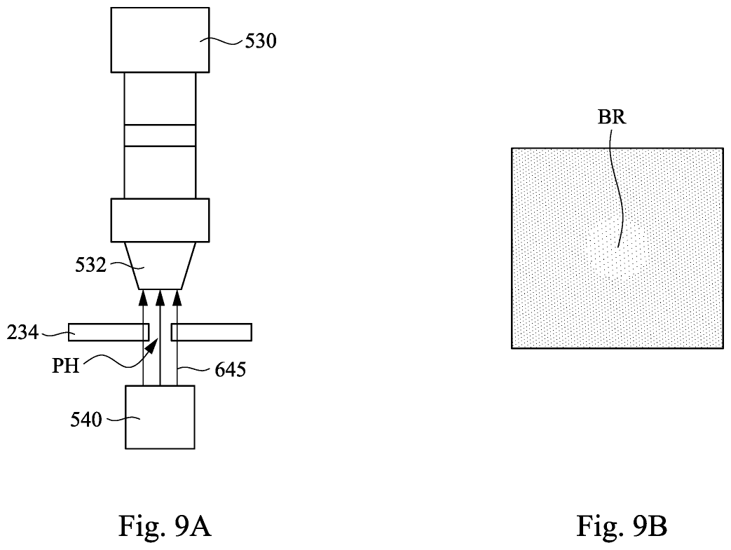

FIG. 9A is a schematic view of performing an inspection process to a pellicle membrane according to some embodiments of the present disclosure. FIG. 9B is an explanatory result of an inspection process according to some embodiments of the present disclosure. Some details of FIG. 9A may be similar to those described with respect to FIGS. 8A and 8B, and will not be repeated for brevity.

FIG. 9A shows a condition where a pin hole PH is present in the pellicle membrane 234. In such condition, a portion of the incident laser beam 645 may pass through the pine hole PH to the image sensor 530. On the other hand, other portions of the incident laser beam 645 may pass through the pellicle membrane 234 to the image sensor 530.

FIG. 9B is an explanatory result of the inspection process described in FIG. 9A. In greater details, FIG. 9B is an image generated by the image sensor 530. In the embodiments where pin hole (e.g., the pin hole PH) is present in the pellicle membrane 234, the incident laser beam 645 may pass through both the pine hole PH and the pellicle membrane 234 to the image sensor 530. However, because the pellicle membrane 234 may scatter the incident laser beam 645, and will reduce the light intensity of the incident laser beam 645. In contrast, light intensity of the incident laser beam 645 that passes through the pine hole PH may not be reduced (or less reduced than the portion of the laser beam 645 passing through the pellicle membrane 234). As a result, a bright region BR may be present in the generated image. Stated another way, if a bright region BR is present in the generated image, this may indicate that a pin hole is present in the pellicle membrane 234.

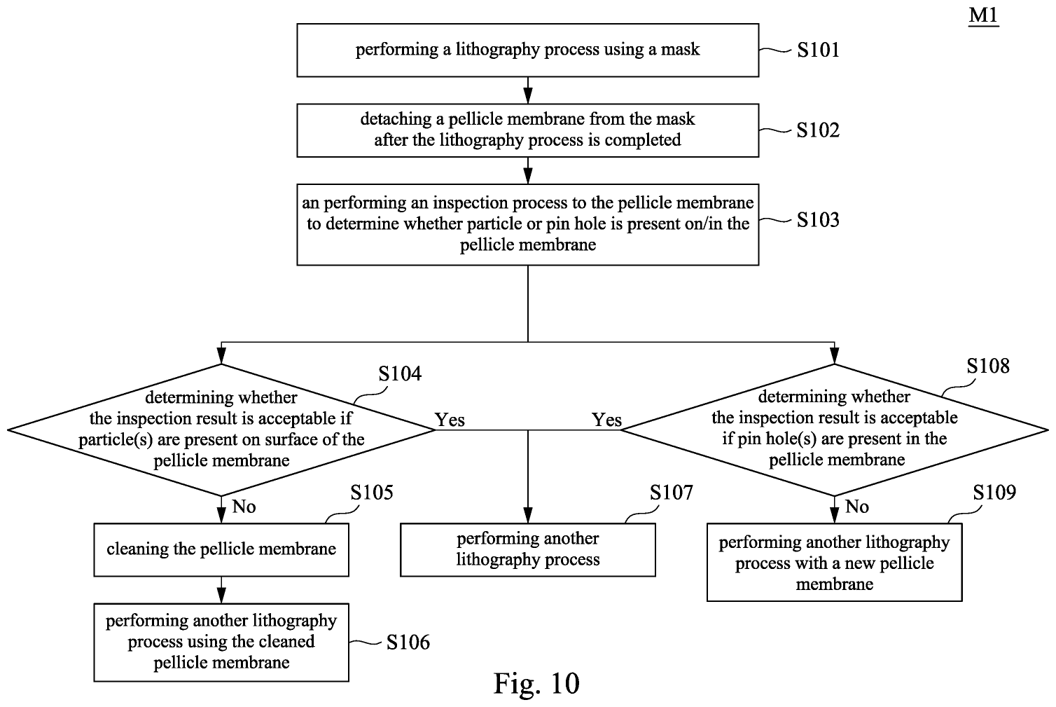

FIG. 10 illustrates a method of an inspection process according to some embodiments of the present disclosure. Although the method M1 described in FIG. 10 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

The method M1 starts at block S101, a lithography process is performed using a mask. In some embodiments, the lithography process is similar to the lithography process as described in FIGS. 1 and 2. In greater details, as discussed in FIG. 3A, during performing a lithography process, a pellicle structure 230 is attached to a mask 330.

The method M1 proceeds to block S102, after the lithography process is completed, a pellicle membrane is detached from the mask. For example, in FIG. 3A, after the lithography process is completed, the pellicle structure 230 is detached from the mask 330.

The method M1 proceeds to block S103, an inspection process is performed to the pellicle membrane to determine whether particle or pin hole is present on/in the pellicle membrane. For example, the inspection process can be performed to the pellicle membrane 234 of the pellicle structure 230 by using the inspection tool 500 as described in FIGS. 4A and 4B and the inspection tool 600 as described in FIG. 7, and the inspection process may be similar to the inspection process as described in FIGS. 4A to 9B. In greater details, the inspection process can be performed by determining whether a dark region or a bright region is present in the image captured by the image sensor 530 as described in FIGS. 4A to 9B. In some embodiments, if there is at least one dark region in the generated image, this indicate that at least one particle is present on surface of the pellicle membrane 234. On the other hand, if there is at least one bright region in the generated image, this indicate that at least one pin hole is present in the pellicle membrane 234.

If there is at least one dark region in the generated image, it is determined that at least one particle is present on surface of the pellicle membrane 234. The method M1 then proceeds to block S104 by determining whether the inspection result is acceptable if particle(s) are present on surface of the pellicle membrane.

In first embodiments, determining whether the inspection result is acceptable can be done by determining whether a size of the particle is smaller than a predetermined value. Here, the “size” of the particle can be the width or the diameter of the particle. In some embodiments, the size of the particle can be calculated based on the size of the dark region in the generated image. Accordingly, determining the size of the particle can also be referred to as determining the size of the dark region in this content, because the size of the dark region is an image of the particle. In some embodiments, if the size of the particle is greater than about 8 μm, the size of the particle is too large and may deteriorate the quality of a lithography process. In such condition, the size of the particle is beyond (e.g., greater) the predetermined value, and the inspection result is determined as unacceptable. On the other hand, if the size of the particle is less than about 8 μm, the size of the particle is too small and may not affect the quality of a lithography process. In such condition, the size of the particle is smaller than the predetermined value, and the inspection result is determined as acceptable. In some embodiments where there are several particles on the pellicle membrane 234, the inspection result is determined as acceptable when sizes of all particles are smaller than the predetermined value. In contrast, the inspection result is determined as unacceptable when the size of at least one of the particles is beyond the predetermined value.

In second embodiments, the determining whether the inspection result is acceptable can be done by determining whether a number of the particle(s) is less than a predetermined value. In some embodiments, if the number of the particle(s) is greater than 0, the inspection result is determined as unacceptable. That is, the inspection result is determined as acceptable when there is no particle on the surface of the pellicle membrane 234. Stated another way, the inspection result is determined as acceptable when there is no dark region in the generated image.

In third embodiments, the determining whether the inspection result is acceptable can be done by determining whether a number of the particle(s) on a first side of the pellicle membrane 234 is less than a first predetermined value and determining whether a size of the particle(s) on a second side of the pellicle membrane 234 is smaller than a second predetermined value. Here, the first side of the pellicle membrane 234 is the first side 234A as described in FIG. 3A, and the second side of the pellicle membrane 234 is the second side 234B as described in FIG. 3A. In some embodiments, when dark region(s) are present in the generated image, this indicates that there may be particle(s) on the first side 234A and/or the second side 234B of the pellicle membrane 234.

In the third embodiments, if the number of the particle(s) on the first side 234A of the pellicle membrane 234 is greater than 0, the inspection result is determined as unacceptable. That is, the inspection result is determined as acceptable when there is no particle on the first side 234A of the pellicle membrane 234. On the other hand, if the size of the particle on the second side 234B of the pellicle membrane 234 is greater than about 8 μm, the size of the particle is too large and may deteriorate the quality of a lithography process. In such condition, the size of the particle is beyond the predetermined value, and the inspection result is determined as unacceptable. On the other hand, if the size of the particle on the second side 234B of the pellicle membrane 234 is less than about 8 μm, the size of the particle is too small and may not affect the quality of a lithography process. Accordingly, the inspection result is determined as acceptable when there is no particle on the first side 234A of the pellicle membrane 234 and the sizes of all particle(s) on the second side 234B of the pellicle membrane 234 are smaller than a predetermined value. However, the inspection result is determined as unacceptable when there is at least on particle on the first side 234A of the pellicle membrane 234 or the size of at least one of the particles on the second side 234B of the pellicle membrane 234 is beyond a predetermined value.

In the condition where particle(s) are present on surface of the pellicle membrane, if the inspection result is determined as unacceptable, the method M1 then proceeds to block S105 by cleaning the pellicle membrane. In greater details, a cleaning process may be performed to remove particle(s) on the pellicle membrane 234. After the pellicle membrane 234 is cleaned, the method M1 then proceeds to block S106 by performing another lithography process using the cleaned pellicle membrane. On the other hand, if the inspection result is determined as acceptable, the method M1 then proceeds to block S107 by performing another lithography process. In greater details, the lithography process can be performed using the original pellicle membrane 234, which is determined as acceptable.

Referring back to block S103, if there is at least one bright region in the generated image, it is determined that at least one pin hole is present in the pellicle membrane 234. The method M1 then proceeds to block S108 by determining whether the inspection result is acceptable if pin hole(s) are present in the pellicle membrane.

In some embodiments, determining whether the inspection result is acceptable can be done by determining whether a size of the pin hole is smaller than a predetermined value. Here, the “size” of the particle can be the width or the diameter of the pin hole. In some embodiments, the size of the pin hole can be calculated based on the size of the bright region in the generated image. Accordingly, determining the size of the pin hole can also be referred to as determining the size of the bright region in this content, because the size of the bright region is an image of the pin hole. In some embodiments, if the size of the particle is greater than about 0.4 μm, the size of the pin hole is too large and may deteriorate the quality of a lithography process. In such condition, the size of the pin hole is beyond the predetermined value, and the inspection result is determined as unacceptable. On the other hand, if the size of the pin hole is less than about 0.3 μm, the size of the particle is too small and may not affect the quality of a lithography process. In such condition, the size of the particle is smaller than the predetermined value, and the inspection result is determined as acceptable. In some embodiments where there are several pin holes in the pellicle membrane 234, the inspection result is determined as acceptable when sizes of all pin holes are smaller than the predetermined value. In contrast, the inspection result is determined as unacceptable when the size of at least one of the pin holes is beyond the predetermined value.

In the condition where pin hole(s) are present in the pellicle membrane, if the inspection result is determined as unacceptable, the method M1 then proceeds to block S109 by performing another lithography process with a new pellicle membrane. In greater details, because pin hole in the pellicle membrane 234 is hard to be repaired. The unacceptable may be discarded, and a new pellicle membrane 234 can be used in the lithography process. On the other hand, if the inspection result is determined as acceptable, the method M1 then proceeds to block S107 by performing another lithography process. In greater details, the lithography process can be performed using the original pellicle membrane 234, which is determined as acceptable.

FIGS. 11A to 11F illustrate cross-sectional views of a pellicle membrane according to some embodiments of the present disclosure. Shown there is a pellicle membrane 710. The pellicle membrane 710 includes a semiconductor layer 711. In some embodiments, the semiconductor layer 711 may include poly silicon, or other suitable semiconductor material. Dielectric layers 712 and 713 are disposed on opposite sides of the semiconductor layer 711. In some embodiments, the dielectric layers 712 and 713 are made of silicon nitride (SiN g), or other suitable dielectric materials. A metal layer 714 is disposed on the dielectric layer 713. In some embodiments, the metal layer 714 is made of molybdenum (Mo), or other suitable metal. A metal layer 715 is disposed on the metal layer 714. In some embodiments, the metal layer 714 is made of ruthenium (Ru), or other suitable metal.

FIGS. 11B to 11F show different types of pin hole in the pellicle membrane 710. In FIG. 11B, the pin hole PH extends through the semiconductor layer 711. In FIG. 11C, the pin hole PH extends through the semiconductor layer 711, the dielectric layer 713, the metal layer 714, and the metal layer 715. In FIG. 11D, the pin hole PH extends through the semiconductor layer 711, the dielectric layer 713, and the metal layer 714, and may be partially in the metal layer 715. In FIG. 11E, the pin hole PH extends through the semiconductor layer 711, the dielectric layer 713, and the metal layer 714, and may be partially in the metal layer 715 and the dielectric layer 712. In FIG. 11F, the pin hole PH may penetrate through the pellicle membrane 710.

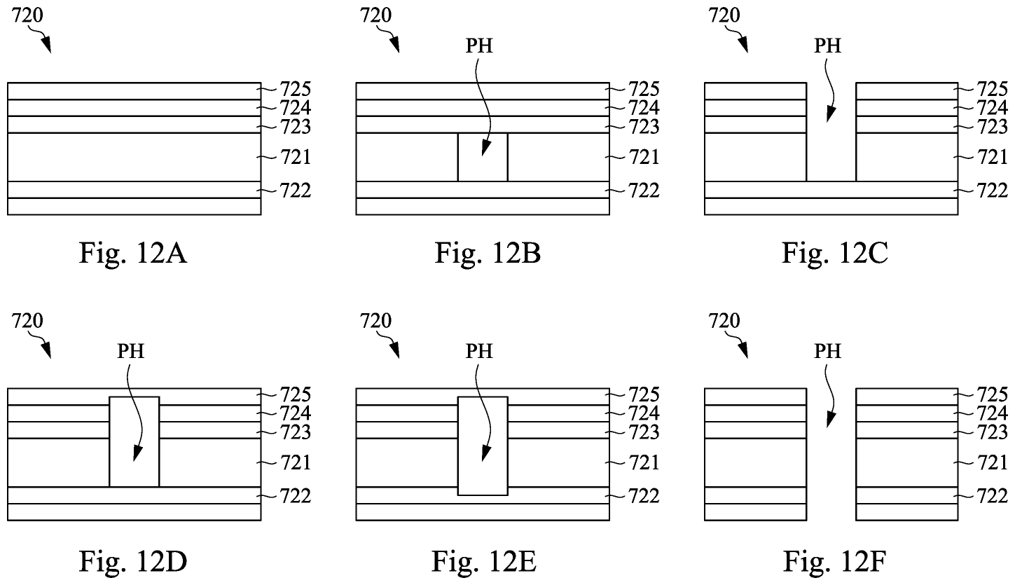

FIGS. 12A to 12F illustrate cross-sectional views of a pellicle membrane according to some embodiments of the present disclosure. Shown there is a pellicle membrane 720. The pellicle membrane 720 includes a semiconductor layer 721. In some embodiments, the semiconductor layer 721 may include poly silicon, or other suitable semiconductor material. Dielectric layers 722 and 724 are disposed on opposite sides of the semiconductor layer 721. In some embodiments, the dielectric layers 722 and 724 are made of silicon nitride (SiN g), or other suitable dielectric materials. A metal layer 723 is disposed on the dielectric layer 722, and a metal layer 725 is disposed on the dielectric layer 724. In some embodiments, the metal layers 723 and 725 are made of molybdenum (Mo), or other suitable metal. A metal layer 726 is disposed on the metal layer 725. In some embodiments, the metal layer 726 is made of ruthenium (Ru), or other suitable metal.

FIGS. 12B to 12F show different types of pin hole in the pellicle membrane 720. In FIG. 12B, the pin hole PH extends through the semiconductor layer 721. In FIG. 12C, the pin hole PH extends through the semiconductor layer 721, the dielectric layer 724, the metal layer 725, and the metal layer 726. In FIG. 12D, the pin hole PH extends through the semiconductor layer 721, the dielectric layer 724, and the metal layer 725, and may be partially in the metal layer 726. In FIG. 12E, the pin hole PH extends through the semiconductor layer 721, the dielectric layer 724, and the metal layer 725, and may be partially in the metal layer 726 and the dielectric layer 722. In FIG. 12F, the pin hole PH may penetrate through the pellicle membrane 720.

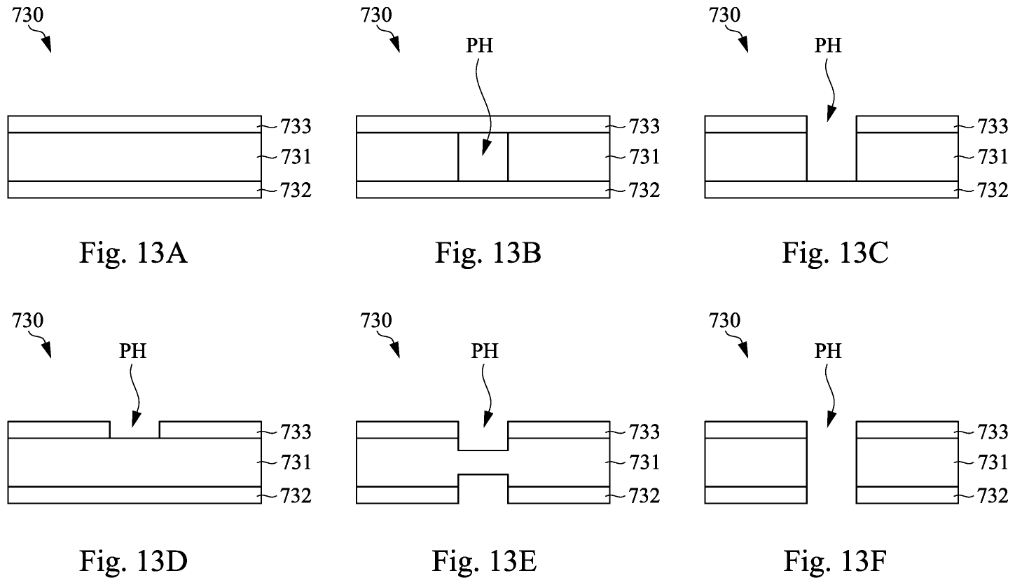

FIGS. 13A to 13F illustrate cross-sectional views of a pellicle membrane according to some embodiments of the present disclosure. Shown there is a pellicle membrane 730. The pellicle membrane 730 includes a silicon-based material 731. In some embodiments, the silicon-based material 731 is made of MoSi, MoSiN, MoSiON, SiC, ZrSi, or other suitable materials. Dielectric layers 732 and 733 are disposed on opposite sides of the silicon-based material 731. In some embodiments, the dielectric layers 732 and 733 are made of silicon nitride (SiNₓ), or other suitable dielectric materials.

FIGS. 13B to 13F show different types of pin hole in the pellicle membrane 730. In FIG. 13B, the pin hole PH extends through the silicon-based material 731. In FIG. 13C, the pin hole PH extends through the silicon-based material 731 and the dielectric layer 733. In FIG. 13D, the pin hole PH extends through the dielectric layer 733. In FIG. 13E, one pin hole PH extends through the dielectric layer 732 and partially in the silicon-based material 731, and another pin hole PH extends through the dielectric layer 733 and partially in the silicon-based material 731. In FIG. 13F, the pin hole PH may penetrate through the pellicle membrane 730.

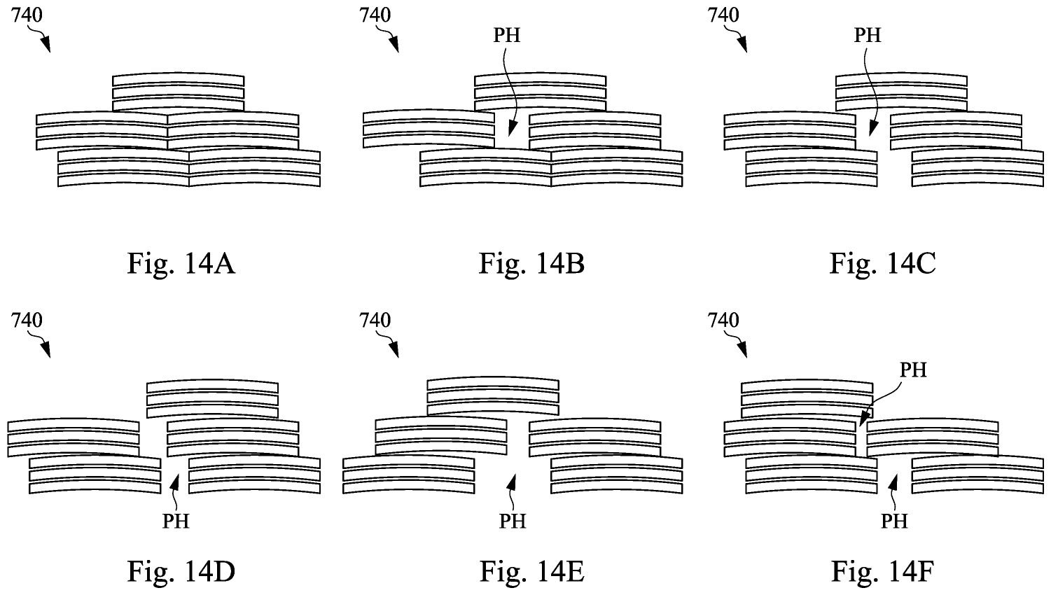

FIGS. 14A to 14F illustrate cross-sectional views of a pellicle membrane according to some embodiments of the present disclosure. Shown there is a pellicle membrane 740. The pellicle membrane 740 is made of a 2-D material, such as graphene.

FIGS. 14B to 14F show different types of pin hole in the pellicle membrane 740. In FIG. 14B, the pin hole PH is inside the pellicle membrane 740. In FIG. 14C, the pin hole PH is at the bottom surface of the pellicle membrane 740. In FIG. 14D, the pin hole PH penetrates through the pellicle membrane 740. In FIG. 14E, the pin hole PH is at the bottom surface of the pellicle membrane 740. In FIG. 14F, one pin hole PH is inside the pellicle membrane 740, and another pin hole PH is at the bottom surface the pellicle membrane 740.

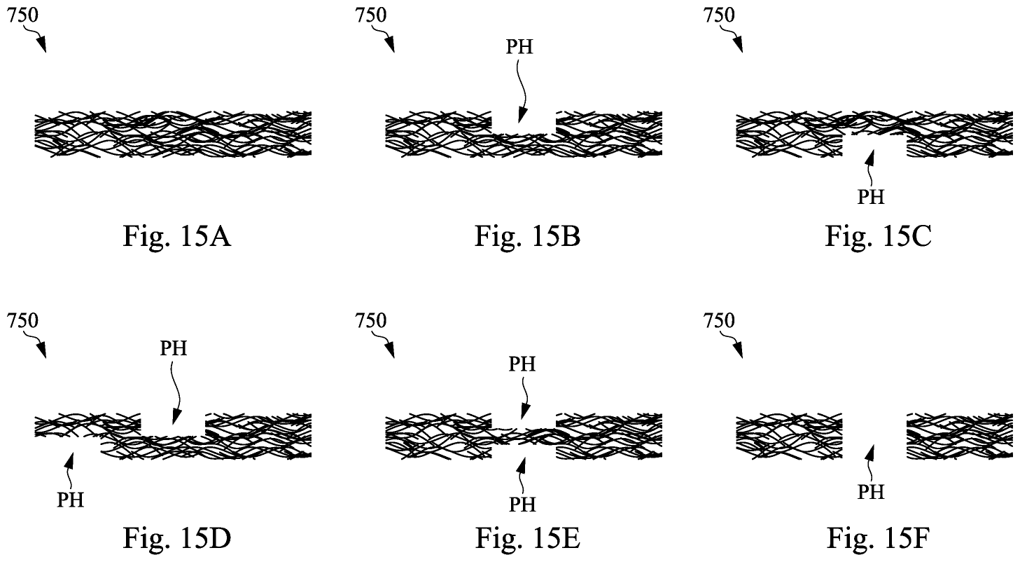

FIGS. 15A to 15F illustrate cross-sectional views of a pellicle membrane according to some embodiments of the present disclosure. Shown there is a pellicle membrane 750. The pellicle membrane 750 is made carbon nanotube, boron nitride (BNNT), SiC nanotube, MoS2, MoSe2, WS2, WSe2 nanotube, or other suitable materials.

FIGS. 15B to 15F show different types of pin hole in the pellicle membrane 750. In FIG. 15B, the pin hole PH is at the top surface of the pellicle membrane 750. In FIG. 15C, the pin hole PH is at the bottom surface of the pellicle membrane 750. In FIG. 15D, one pin hole PH is at the top surface of the pellicle membrane 750 and another pin hole is at the bottom surface of the pellicle membrane 750, in which two pin holes PH are laterally shift from each other. In FIG. 15E, one pin hole PH is at the top surface of the pellicle membrane 750 and another pin hole is at the bottom surface of the pellicle membrane 750, in which two pin holes PH vertically overlap with each other. In FIG. 15F, the pin hole PH penetrates through the pellicle membrane 750.

Based on the above discussions, it can be seen that the present disclosure offers advantages. It is understood, however, that other embodiments may offer additional advantages, and not all advantages are necessarily disclosed herein, and that no particular advantage is required for all embodiments. Embodiments of the present disclosure provides a method for inspecting whether particles are present on surface of a pellicle membrane or whether pin holes are present in the pellicle membrane. The inspection process can ensure the cleanness of pellicle membrane to protect mask from particle contamination, or the pellicle rupture due to the pin hole.

In some embodiments of the present disclosure, a method includes performing a lithography process using a mask and a pellicle membrane; detaching the pellicle membrane from the mask after the lithography process is completed; performing an inspection process to the pellicle membrane, the inspection process including generating a laser beam toward the pellicle membrane from a laser source, such that the laser beam passes through the pellicle membrane; and generating an image by receiving the laser beam passing through the pellicle membrane using an image sensor; and determining whether a particle is present on the pellicle membrane or a pin hole is present in the pellicle membrane based on the image.

In some embodiment, the inspection process further includes reflecting the laser beam passing through the pellicle membrane by a reflector, such that the reflected laser beam passes through the pellicle membrane again and is received by the image sensor.

In some embodiment, the laser source and the image sensor are disposed on opposite sides of the pellicle membrane during performing the inspection process.

In some embodiment, a particle is determined as on the pellicle membrane when a dark region is present in the image, the dark region being darker than a background of the image.

In some embodiment, a pin hole is determined as in the pellicle membrane when a bright region is present in the image, the bright region being brighter than a background of the image.

In some embodiment, the method further includes determining whether a size of the particle is lower than a predetermined value when a particle is determined as on the pellicle membrane; and cleaning the pellicle membrane when the size of the particle is determined as greater than the predetermined value.

In some embodiment, the method further includes cleaning the pellicle membrane when a particle is determined as on the pellicle membrane.

In some embodiment, during performing the lithography process the pellicle membrane has a first side facing the mask and a second side facing the mask, when a particle is determined as on the pellicle membrane, the method further includes determining whether a size of the particle is lower than a predetermined value if the particle is on the first side of the pellicle membrane; and determining whether a number of the particle is greater than a predetermined value if the particle is on the second side of the pellicle membrane.

In some embodiment, the method further includes determining whether a size of the pin hole is lower than a predetermined value when a pin hole is determined as in the pellicle membrane; and performing another lithography using a new pellicle membrane when the size of the pin hole is determined as greater than the predetermined value.

In some embodiments of the present disclosure, a method includes performing a lithography process using a mask and a pellicle membrane; detaching the pellicle membrane from the mask after the lithography process is completed; generating an image of the pellicle membrane using an inspection tool; and determining whether a dark region or a bright region is present in the image, wherein a particle is determined as on the pellicle membrane when a dark region is determined as present in the image, and a pin hole is determined as in the pellicle membrane when a bright region is determined as present in the image.

In some embodiment, the inspection tool includes a laser source and an image sensor disposed on opposite sides of the pellicle membrane, and generating the image of the pellicle membrane includes generate a laser beam from the laser source toward the pellicle membrane; and receiving the laser beam passing through the pellicle membrane by the image sensor.

In some embodiment, the inspection tool includes a laser source, an image sensor, and a reflector, and generating the image of the pellicle membrane includes generate a laser beam from the laser source toward the pellicle membrane; reflecting the laser beam passing through the pellicle membrane, such that the reflected laser beam passes through the pellicle membrane; and receiving the reflected laser beam passing through the pellicle membrane by the image sensor.

In some embodiment, the method further includes placing the pellicle membrane on a pellicle holder connected to the reflector prior to generating the image of the pellicle membrane.

In some embodiment, during performing the lithography process the pellicle membrane has a first side facing the mask and a second side facing the mask, and the pellicle membrane is placed on the pellicle holder such that the first side of the pellicle membrane faces the reflector.

In some embodiment, the method further includes determining whether a size of the dark region is lower than a predetermined value when a dark region is determined as in the image; and cleaning the pellicle membrane when the size of the dark region is determined as greater than the predetermined value.

In some embodiment, the method further includes determining whether a size of the bright region is lower than a predetermined value when a bright region is determined as in the image; and performing another lithography using a new pellicle membrane when the size of the bright region is determined as greater than the predetermined value.

In some embodiments of the present disclosure, a method includes placing a pellicle membrane on a pellicle holder; performing an inspection process to the pellicle membrane, the inspection process including generating a laser beam toward the pellicle membrane from a laser source, such that the laser beam passes through the pellicle membrane; and generating, using an image sensor, an image by receiving the laser beam passing through the pellicle membrane; determining whether an inspection result is acceptable; and performing a lithography process using the pellicle membrane when the inspection result is determined as acceptable.

In some embodiment, the inspection result is determined as acceptable when a size of a dark region in the image is less than a predetermined value.

In some embodiment, the inspection result is determined as acceptable when a size of a bright region in the image is less than a predetermined value.

In some embodiment, the inspection result is determined as acceptable when there is no dark region in the image.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a lithography process using a mask and a pellicle membrane;
detaching the pellicle membrane from the mask after the lithography process is completed;
performing an inspection process to the pellicle membrane, the inspection process comprising:
generating a laser beam toward the pellicle membrane from a laser source, such that the laser beam passes through the pellicle membrane; and
generating an image by receiving the laser beam passing through the pellicle membrane using an image sensor; and
determining whether a particle is present on the pellicle membrane or a pin hole is present in the pellicle membrane based on the image.

2. The method of claim 1, wherein the inspection process further comprises:
reflecting the laser beam passing through the pellicle membrane by a reflector, such that the reflected laser beam passes through the pellicle membrane again and is received by the image sensor.

3. The method of claim 1, wherein the laser source and the image sensor are disposed on opposite sides of the pellicle membrane during performing the inspection process.

4. The method of claim 1, wherein a particle is determined as on the pellicle membrane when a dark region is present in the image, the dark region being darker than a background of the image.

5. The method of claim 1, wherein a pin hole is determined as in the pellicle membrane when a bright region is present in the image, the bright region being brighter than a background of the image.

6. The method of claim 1, further comprising:
determining whether a size of the particle is lower than a predetermined value when a particle is determined as on the pellicle membrane; and
cleaning the pellicle membrane when the size of the particle is determined as greater than the predetermined value.

7. The method of claim 1, further comprising cleaning the pellicle membrane when a particle is determined as on the pellicle membrane.

8. The method of claim 1, wherein during performing the lithography process the pellicle membrane has a first side facing the mask and a second side facing the mask, when a particle is determined as on the pellicle membrane, the method further comprises:
determining whether a size of the particle is lower than a predetermined value if the particle is on the first side of the pellicle membrane; and
determining whether a number of the particle is greater than a predetermined value if the particle is on the second side of the pellicle membrane.

9. The method of claim 1, further comprising:
determining whether a size of the pin hole is lower than a predetermined value when a pin hole is determined as in the pellicle membrane; and
performing another lithography using a new pellicle membrane when the size of the pin hole is determined as greater than the predetermined value.

10. A method, comprising:
performing a lithography process using a mask and a pellicle membrane;
detaching the pellicle membrane from the mask after the lithography process is completed;
generating an image of the pellicle membrane using an inspection tool; and
determining whether a dark region or a bright region is present in the image, wherein a particle is determined as on the pellicle membrane when a dark region is determined as present in the image, and a pin hole is determined as in the pellicle membrane when a bright region is determined as present in the image.

11. The method of claim 10, wherein the inspection tool comprises a laser source and an image sensor disposed on opposite sides of the pellicle membrane, and generating the image of the pellicle membrane comprises:
generate a laser beam from the laser source toward the pellicle membrane; and
receiving the laser beam passing through the pellicle membrane by the image sensor.

12. The method of claim 10, wherein the inspection tool comprises a laser source, an image sensor, and a reflector, and generating the image of the pellicle membrane comprises:
generate a laser beam from the laser source toward the pellicle membrane;
reflecting the laser beam passing through the pellicle membrane, such that the reflected laser beam passes through the pellicle membrane; and
receiving the reflected laser beam passing through the pellicle membrane by the image sensor.

13. The method of claim 12, further comprising placing the pellicle membrane on a pellicle holder connected to the reflector prior to generating the image of the pellicle membrane.

14. The method of claim 13, wherein during performing the lithography process the pellicle membrane has a first side facing the mask and a second side facing the mask, and the pellicle membrane is placed on the pellicle holder such that the first side of the pellicle membrane faces the reflector.

15. The method of claim 10, further comprising:
determining whether a size of the dark region is lower than a predetermined value when a dark region is determined as in the image; and
cleaning the pellicle membrane when the size of the dark region is determined as greater than the predetermined value.

16. The method of claim 10, further comprising:
determining whether a size of the bright region is lower than a predetermined value when a bright region is determined as in the image; and
performing another lithography using a new pellicle membrane when the size of the bright region is determined as greater than the predetermined value.

17. A method, comprising:
placing a pellicle membrane on a pellicle holder;
performing an inspection process to the pellicle membrane, the inspection process comprising:
generating a laser beam toward the pellicle membrane from a laser source, such that the laser beam passes through the pellicle membrane; and
generating, using an image sensor, an image by receiving the laser beam passing through the pellicle membrane;
determining whether an inspection result is acceptable; and
performing a lithography process using the pellicle membrane when the inspection result is determined as acceptable.

18. The method of claim 17, wherein the inspection result is determined as acceptable when a size of a dark region in the image is less than a predetermined value.

19. The method of claim 17, wherein the inspection result is determined as acceptable when a size of a bright region in the image is less than a predetermined value.

20. The method of claim 17, wherein the inspection result is determined as acceptable when there is no dark region in the image.
